(19) United States
(12) Patent Application Publication
(10) Pub. No.: US 2014/0110725 A1
(43) Pub. Date: Apr. 24, 2014

(54) THIN GLASS SUBSTRATE AND FLAT PANEL DISPLAY INCLUDING THE SAME

(71) Applicant: SAMSUNG DISPLAY CO., LTD., Yongin-si (KR)

(72) Inventor: Jin-Woo LEE, Yongin-City (KR)

(73) Assignee: SAMSUNG DISPLAY CO., LTD., Yongin-si (KR)

(21) Appl. No.: 13/758,908

(22) Filed: Feb. 4, 2013

(30) Foreign Application Priority Data
Oct. 22, 2012 (KR) 10-2012-0117540

(51) Int. Cl. B32B 3/26; H01L 33/48

(52) U.S. Cl. CPC B32B 3/266; H01L 33/48
USPC 257/88; 428/210; 428/134; 428/138

(57) ABSTRACT

A thin glass substrate and a flat panel display (FPD) including the same. The thin glass substrate includes a transparent base member and a transparent mesh pattern formed on one surface of the base member. The base member may be stably supported by the mesh pattern and tension is provided when the base member is deformed so that it is possible to prevent the base member from being broken. In addition, the mesh pattern disperses shock or stress applied to the base member, and it is possible to suppress electromagnetic wave interference from the outside.

### CROSS-REFERENCE TO RELATED APPLICATION

This application claims priority to and the benefit of Korean Patent Application No. 10-2012-0117540, filed on Oct. 22, 2012, in the Korean Intellectual Property Office, the entire content of which is incorporated herein by reference.

### BACKGROUND

1. Field

The following description relates to a thin glass substrate used for a flat panel display (FPD), and more particularly, to a thin glass substrate having improved durability and a flat panel display (FPD) including the same.

2. Description of the Related Art

In general, a flat panel display (FPD), such as an organic light emitting display (OLED) or a liquid crystal display (LCD), is manufactured using a glass substrate.

Since the glass substrate has high transmittance, the glass substrate is suitable as a material for a display device. However, due to the weight of the glass substrate, as the size of the display device increases, the weight of the display device increases. Therefore, the display device may be easily damaged.

Recently, with the increase in the size of the display device, it is required that the thickness of the display device be reduced. In order to reduce the thickness of the display device, it is necessary to reduce the thickness of the substrate.

Since the thin glass substrate having a thickness of no more than 0.5 mm is easily bent and is vulnerable to shock, the durability of the display device is deteriorated.

In addition, in order to manufacture the display device on the thin glass substrate, a supporting substrate is necessary. A sacrificial layer is formed on the supporting substrate and the glass substrate is attached onto the sacrificial layer. After manufacturing the display device on the glass substrate, the glass substrate is separated from the supporting substrate. Therefore, since processes of attaching and separating the glass substrate are added, manufacturing processes become complicated and contamination and damage may be generated in the processes of attaching and separating the glass substrate.

### SUMMARY

An aspect of an embodiment of the present invention is directed toward a thin glass substrate that may be prevented from being damaged in manufacturing processes.

An aspect of an embodiment of the present invention is directed toward a thin glass substrate having improved durability.

An aspect of an embodiment of the present invention is directed toward a flat panel display (FPD) including a glass substrate capable of suppressing electromagnetic wave interference.

In order to achieve the foregoing and/or other aspects of the present invention, an embodiment of the present invention provides a thin glass substrate, including a transparent base member and a transparent mesh pattern formed on one surface of the base member.

An embodiment of the present invention provides a flat panel display (FPD), including a thin glass substrate including a transparent base member and a transparent mesh pattern formed on one surface of the base member, an insulating substrate provided to face the other surface of the base member, a light emitting element array provided between the base member and the insulating substrate, and a sealing material adhered to the base member and the insulating substrate to surround the light emitting element array.

in one embodiment, the base member has a thickness of 0.05 mm to 0.5 mm. In one embodiment, the mesh pattern has a thickness of 100 nm to 300 nm.

In one embodiment, the mesh pattern is formed of a conductive material selected from the group consisting of AZO, ITO, IZO, and ITZO. In one embodiment, the mesh pattern includes a plurality of polygonal apertures.

In the thin glass substrate according to an embodiment of the present invention, the mesh pattern is formed on one surface of the base member. The base member may be stably supported by the mesh pattern and tension is provided when the base member is deformed so that it is possible to prevent the base member from being broken. In addition, the mesh pattern disperses shock or stress applied to the base member to improve durability and suppresses electromagnetic wave interference from the outside.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a perspective view illustrating a thin glass substrate according to an embodiment of the present invention;

FIG. 2 is a sectional view illustrating a thin glass substrate according to an embodiment of the present invention;

FIG. 3 is a sectional view illustrating an operation of a thin glass substrate according to an embodiment of the present invention;

FIG. 4 is a sectional view illustrating a flat panel display (FPD) according to an embodiment of the present invention; and

FIG. 5 is a sectional view illustrating an FPD according to another embodiment of the present invention.

### DETAILED DESCRIPTION

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. In addition, when an element is referred to as being “on” another element, it can be directly on another element or be indirectly on another element with one or more intervening elements interposed therebetween. Also, when an element is referred to as being “connected to” another element, it can be directly connected to another element or be indirectly connected to another element with one or more intervening elements interposed therebetween. Hereinafter, like reference numerals refer to like elements.

The present invention now will be described more fully with reference to the accompanying drawings, in which exemplary embodiments of the present invention are shown. This invention may, however, be embodied in many different forms and should not be construed as being limited to the embodiments set forth herein; rather, these embodiments are provided so that this disclosure will be thorough and complete, and will fully convey the concept of the invention to those skilled in the art.

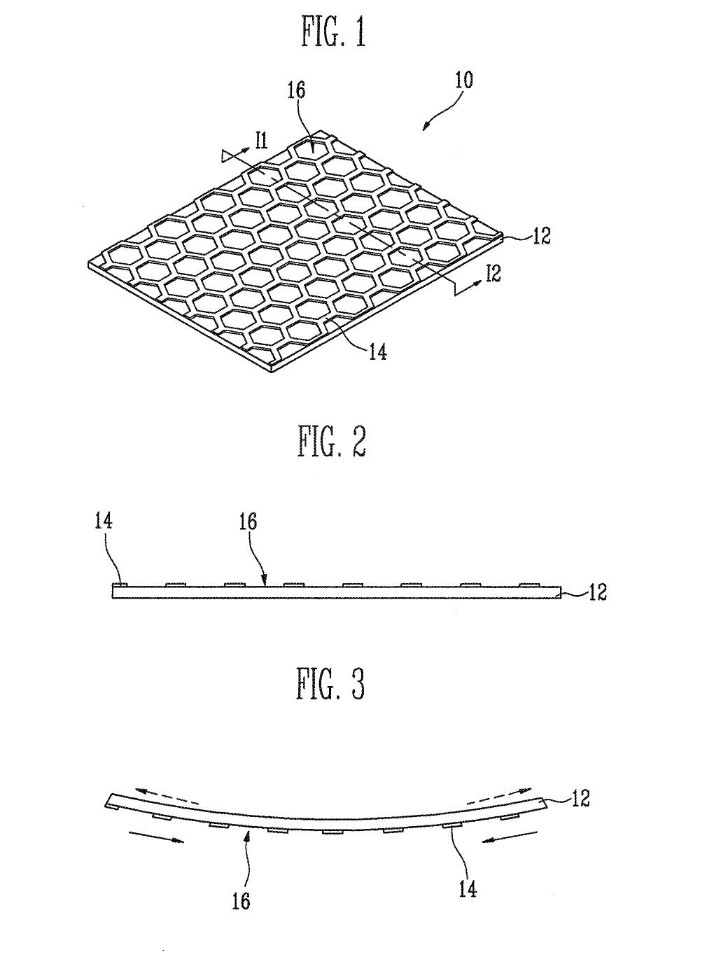

FIG. 1 is a perspective view illustrating a thin glass substrate according to an embodiment of the present invention. FIG. 2 is a sectional view taken along the line I1-I2 of FIG. 1.

Referring to FIGS. 1 and 2, a thin glass substrate 10 includes a transparent base member 12 and a transparent mesh pattern formed on one surface of the base member 12.

In one embodiment, the mesh pattern 14 is formed on the entire one surface of the base member 12 and includes a plurality of apertures 16 distributed over the entire one surface of the base member 12. For example, the mesh pattern 14 is honeycomb, mesh, and grid-shaped. In FIG. 1, the hexagonal apertures 16 are uniformly arranged. However, a plurality of circular or polygonal apertures 16 may be uniformly or non-uniformly arranged.

The transparent base member 12 may be formed of glass or quartz as a thin film and may have a thickness of 0.05 mm to 0.5 mm.

The transparent mesh pattern 14 may be formed of one conductive material selected from the group consisting of Al-doped Zinc Oxide (AZO), indium tin oxide (IOT), indium zinc oxide (IZO), and indium tin zinc oxide (ITZO) and may have a thickness of 100 nm to 300 nm. When the thickness of the mesh pattern 14 is smaller than 100 nm, it is difficult to sufficiently support the base member 12. When the thickness of the mesh pattern 14 is larger than 300 nm, the entire thickness of the glass substrate increases so that it is difficult to make a display device thin and to apply the glass substrate to a flexible display device.

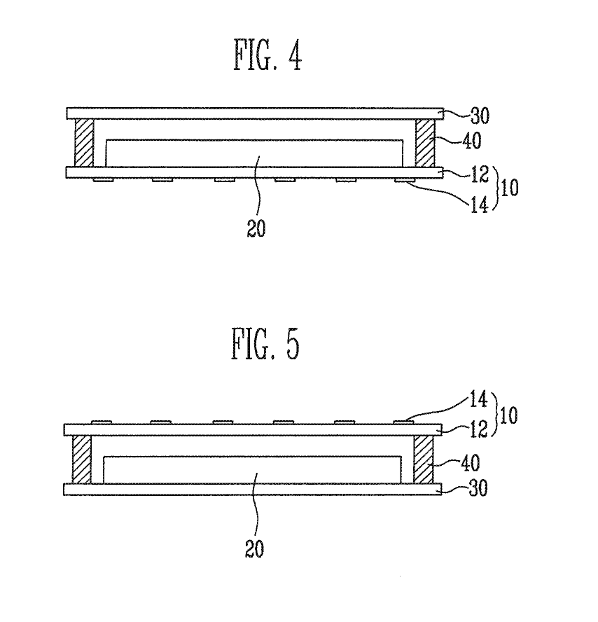

A thin film transistor (TFT), a capacitor, and a light emitting element may be manufactured on the base member 12 of the thin glass substrate 10 having the above structure by a semiconductor process. For example, in order to form a conductive layer or an insulating layer on the base member 12, a deposition process is performed in a chamber at high temperature and at gas atmosphere. At this time, due to a difference in a thermal expansive coefficient between a substrate support (not shown) formed of a metal or an inorganic material and the base member 12, as illustrated in FIG. 3, the base member 12 is deformed (bent) and may be further broken or damaged.

However, in the thin glass substrate 10 according to an embodiment of the present invention, in the above-described environment, the deformation of the base member 12 is suppressed by the mesh pattern 14 formed on one surface of the base member 12, and the base member 12 is supported by the mesh pattern 14. Therefore, the thin glass substrate 10 is not broken. For example, as illustrated in FIG. 3, when the peripheral parts of the base member 12 are bent upward, tension is applied by the mesh pattern 14 as illustrated by an arrow (a solid line) so that bending may be suppressed. When the center of the base member 12 is bent downward, tension is applied by the mesh pattern 14 as illustrated by an arrow (a dotted line) so that bending may be suppressed.

When the mesh pattern 14 is regularly formed, tension is uniformly applied over the entire surface of the base member 12 so that the base member 12 may maintain a stable state. However, the degree or position of bending is estimated to control the size or density (distribution) of the apertures 16 or the distance (width) between the apertures 16 may be controlled. The size of the aperture 16 in the position where the degree of bending is large may be reduced in comparison with the other apertures 16, and the density of the apertures 16 at the position may be increased in comparison with the other apertures 16 at other positions.

In addition, since the mesh pattern 14 disperses shock or stress applied by the base member 12, the durability of the thin glass substrate 10 may be improved.

Although the mesh pattern 14 is formed of a transparent material, since the apertures 16 are related to the amount of transmission of light, the size or density (distribution) of the apertures 16 or the distance (width) between the apertures 16 may be determined based on the amount of transmission of light.

A conductive material may be deposited on one surface of the base member 12 and may be patterned by a photolithography process and an etching process using a mask to form the mesh pattern 14.

The thin glass substrate 10 having the above structure may be used as an element substrate or an encapsulation substrate of a flat panel display (FPD).

FIG. 4 is a sectional view illustrating an FPD including the thin glass substrate 10 according to an embodiment of the present invention, in which the thin glass substrate 10 is used as the element substrate.

Referring to FIG. 4, an insulating substrate 30 is provided on the thin glass substrate 10 to face the base member 12.

The thin glass substrate 10 includes a display area and a non-display area around the display area. The insulating substrate 30 may be provided on the display area, and a part of the non-display area of the thin glass substrate 10. The insulating substrate 30 may be formed of one material selected from the group consisting of glass, metal, and plastic.

A light emitting element array 20 is provided between the base member 12 and the insulating substrate 30, and a sealing material 40 is formed between the base member 12 and the insulating substrate 30 to surround the light emitting element array 20. The sealing material 40 is adhered to the base member 12 and the insulating substrate 30 to seal up the light emitting element array 20.

The light emitting element array 20 may be formed to contact the base member 12 of the display area. The light emitting element array 20 may have a structure in which a plurality of light emitting elements are connected between a plurality of scan lines and data lines in a matrix. The light emitting element may be formed of an organic light emitting diode (OLED). The light emitting element array 20 may include the TFT and the capacitor for driving the OLED. The light emitting element array 20 including the TFT and the capacitor may be manufactured using a suitable semiconductor process.

Since the FPD according to the embodiment of the present invention may be protected or prevented from being broken in the manufacturing process by the operation of the above-described mesh pattern 14 and may have high durability, the FPD may be easily dealt with.

FIG. 5 is a sectional view illustrating an FPD including the thin glass substrate 10 according to another embodiment of the present invention, in which the thin glass substrate 10 is used as the encapsulation substrate.

Referring to FIG. 5, the thin glass substrate 10 is provided to face the insulating substrate 30.

The insulating substrate 30 includes a display area and a non-display area around the display area. The thin glass substrate 10 may be provided on the display area and a part of the non-display area of the insulating substrate 30. The insulating substrate 30 may be formed of one material selected from the group consisting of glass, metal, and plastic.

The light emitting element array 20 is provided between the insulating substrate 30 and the base member 12 of the thin glass substrate 10, and the sealing material 40 is formed between the base member 12 and the insulating substrate 30 to surround the light emitting element array 20. The sealing material 40 is adhered to the base member 12 and the insulating substrate 30 to seal up the light emitting element array 20.

The light emitting element array 20 may be formed to contact the insulating substrate 30 of the display area. The light emitting element array 20 may have the structure in which the plurality of light emitting elements are connected between the plurality of scan lines and data lines in a matrix. The light emitting element may be formed of the OLED. The light emitting element array 20 may include the TFT and the capacitor for driving the OLED. The light emitting element array 20 including the TFT and the capacitor may be manufactured using a suitable semiconductor process.

Since the FPD according to the embodiment of the present invention may be prevented or protected from being broken in the manufacturing process by the operation of the above-described mesh pattern 14 and may have high durability, the FPD may be easily dealt with. In addition, electromagnetic wave interference from the outside may be suppressed by the mesh pattern 14 formed on one surface of the base member 12. In order to maximally suppress the electromagnetic wave interference, the area of the mesh pattern 14 should be as large as possible to increase conductivity. However, when the size of the apertures 16 is excessively reduced, the amount of transmission of light is reduced so that applicability as the encapsulation substrate may be deteriorated.

When the thin glass substrate 10 according to the embodiment of the present invention is used for the FPD, the mesh pattern 14 may be formed only in the non-display area. However, in order to maximize the effect of the present invention, the mesh pattern 14 may be formed on the entire surface including the display area and the non-display area.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A thin glass substrate, comprising:
a transparent base member; and
a transparent mesh pattern on one surface of the base member.

2. The thin glass substrate as claimed in claim 1, wherein the base member has a thickness of 0.05 mm to 0.5 mm.

3. The thin glass substrate as claimed in claim 1, wherein the mesh pattern has a thickness of 100 nm to 300 nm.

4. The thin glass substrate as claimed in claim 1, wherein the mesh pattern is formed of a conductive material.

5. The thin glass substrate as claimed in claim 4, wherein the conductive material is one selected from the group consisting of AZO, ITO, IZO, and ITZO.

6. The thin glass substrate as claimed in claim 1, wherein the mesh pattern comprises a plurality of polygonal apertures.

7. The thin glass substrate as claimed in claim 1, wherein the mesh pattern comprises a plurality of circular apertures.

8. A flat panel display (FPD), comprising:
a thin glass substrate comprising a transparent base member and a transparent mesh pattern on one surface of the base member;
an insulating substrate facing another surface of the base member;
a light emitting element array between the base member and the insulating substrate; and
a sealing material between the base member and the insulating substrate to surround the light emitting element array.

9. The FPD as claimed in claim 8, wherein the base member has a thickness of 0.05 mm to 0.5 mm.

10. The FPD as claimed in claim 8, wherein the mesh pattern has a thickness of 100 nm to 300 nm.

11. The FPD as claimed in claim 8, wherein the mesh pattern is composed of a conductive material.

12. The FPD as claimed in claim 11, wherein the conductive material is one selected from the group consisting of AZO, ITO, IZO, and ITZO.

13. The FPD as claimed in claim 8, wherein the mesh pattern comprises a plurality of polygonal apertures.

14. The FPD as claimed in claim 8, wherein the mesh pattern comprises a plurality of circular apertures.

15. The FPD as claimed in claim 8, wherein the light emitting element array contacts the base member.

16. The FPD as claimed in claim 8, wherein the light emitting element array contacts the insulating substrate.

17. The FPD as claimed in claim 8, wherein the insulating substrate is composed of one selected from the group consisting of glass, metal, and plastic.

18. The FPD as claimed in claim 8, wherein the insulating substrate is composed of an opaque material.

19. The FPD as claimed in claim 8, wherein the sealing material is adhered to the base member and the insulating substrate to seal up the light emitting element array.
